(19) United States
(12) Patent Application Publication
(10) Pub. No.: US 2011/0253413 A1
(43) Pub. Date: Oct. 20, 2011

(54) POWER SUPPLY HAVING BREATHABLE WATER REPELLING MEMBRANE STRUCTURE

(75) Inventors: Yi-Jen LU, Jiaoxi Township (TW); Ya-Tung I, New Taipei City (TW); Wen-Chi Chen, Taipei City (TW)

(73) Assignee: LITE-ON TECHNOLOGY CORPORATION, Taipei City (TW)

(21) Appl. No.: 13/086,615

(22) Filed: Apr. 14, 2011

(30) Foreign Application Priority Data
Apr. 19, 2010 (TW) 099207047

(51) Int. Cl. H05K 5/06

(52) U.S. Cl. 174/50.51

(57) ABSTRACT

Instantly disclosed power supply utilizes a breathable water repelling structure to provide obstruction-less air passage while preventing undesirable intrusion of water/fluids, thus enabling more secure and efficient heat-dissipation. The power supply includes a housing unit having at least one ventilation port; an electronic module disposed in the housing unit; at least one breathable water-repelling membrane unit sealingly covering the ventilation port; and at least one membrane protection unit correspondingly arranged over the breathable water-repelling membrane unit. The power supply can further include a fire-resisting member to prevent the breathable water-repelling membrane unit from catching fire.

### FIELD OF THE INVENTION

The instant disclosure relates to a power supply having a water repelling structure, and more specifically, to a power supply having breathable water repelling membrane unit for improving heat dissipating capability while retaining resistance to water damage.

### BACKGROUND

Power supplies, such as power converters and adaptors, are typically self-contained electronic units that transform/condition power from one or more power sources for supplying power to one or more loads. Power supplies usually comprises electronic modules that are designed to perform functions such as transforming direct current (DC) to alternating current (AC) for supplying power to an AC load, transforming AC to DC for supplying power to an DC load, and/or conditioning/regulating power within the same type of current source. Waterproofing measures are of paramount importance for the power supplies, which are responsible for directly handling electric currents, to prevent electric shortage and other accidents. To prevent water/fluid damage to the power modules, conventional power supplies often employ water-tight housing units having openings only for passing necessary wires.

Like all the modern electronics sharing the design trends toward miniaturization, the physical dimension of modern power supplies continues to shrink, while the power output requirement continues to rise. However, the operation of electronic devices generates wasted energy in the form of heat, and the small-sized and tightly-enclosed housing structures of the modern miniature electronics lack heat dissipating capacity. Thus, heat dissipation becomes an growingly important issue of modern electronics design, as the heat generated by high powered modern electronics will likely cause damage to the device. Nevertheless, the structural balance between water/fluid proofing capability and heat-dissipating capacity of a modern miniature electronic device is not always easy to find.

### SUMMARY

It is an objective of the instant disclosure to provide a power supply that utilizes a breathable water-repelling structure. The power supply includes a housing unit having at least one ventilation port, an electronic module disposed in the housing unit, at least one breathable water-repelling membrane unit sealingly covering the ventilation port for preventing water/fluid from entering the housing unit, and at least one membrane protection unit correspondingly arranged over the breathable water-repelling membrane unit for protecting the membrane unit from external harm.

The breathable water-repelling structure according to the instant disclosure may provide obstruction-less air passage between the interior and exterior of the housing unit while preventing undesirable intrusion of water/fluid into the housing unit, thus ensuring secure and efficient heat-dissipation.

The power supply in accordance with the instant disclosure may include at least one airflow inducing device to facilitate better heat-exchange. The power supply may further include a fire-resisting member to prevent the breathable water-repelling membrane unit from catching fire in the event of an overheating accident.

The above characteristics of the instant disclosure will become more readily apparent to those of ordinary skill in the art after reviewing the following detailed description and the accompanying drawings.

### BRIEF DESCRIPTION OF THE DRAWINGS

FIG. 1 illustrates a perspective overview of a power supply in accordance with the instant disclosure.

FIG. 2A illustrates an explosive diagram of the power supply in accordance with one embodiment of the instant disclosure.

FIG. 2B illustrates an alternative arrangement of the power supply in accordance with another embodiment instant disclosure.

FIG. 3 illustrates a schematic over-head view showing one internal arrangement of the power supply in accordance with the instant disclosure.

FIG. 4 illustrates an explosive diagram of the power supply in accordance with another embodiment of the instant disclosure.

FIG. 5 illustrates a schematic over-head view showing another arrangement of the power supply in accordance with another embodiment of the instant disclosure.

FIG. 6 illustrates a schematic over-head view showing yet another internal arrangement of the power supply in accordance with the instant disclosure.

### DETAILED DESCRIPTION

The instant disclosure will be described more specifically with reference to the following embodiments. It is to be noted that the following descriptions of preferred embodiments are provided herein for purpose of illustration and description. It is not intended to be exhaustive or limiting to the precise form disclosed.

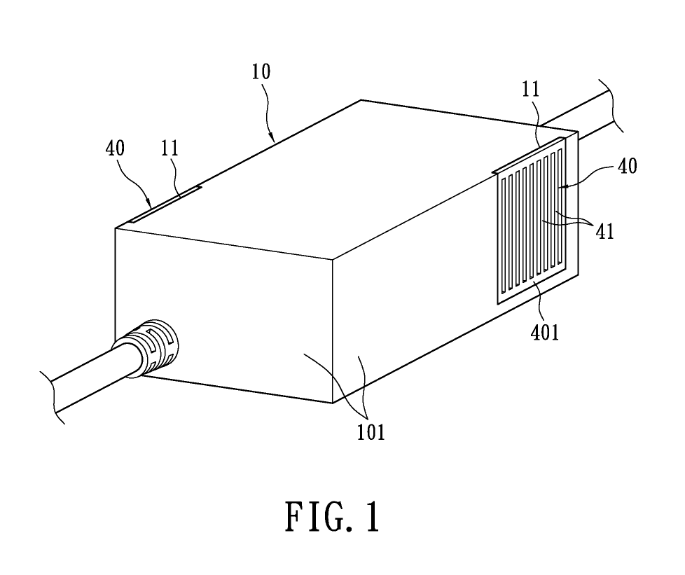

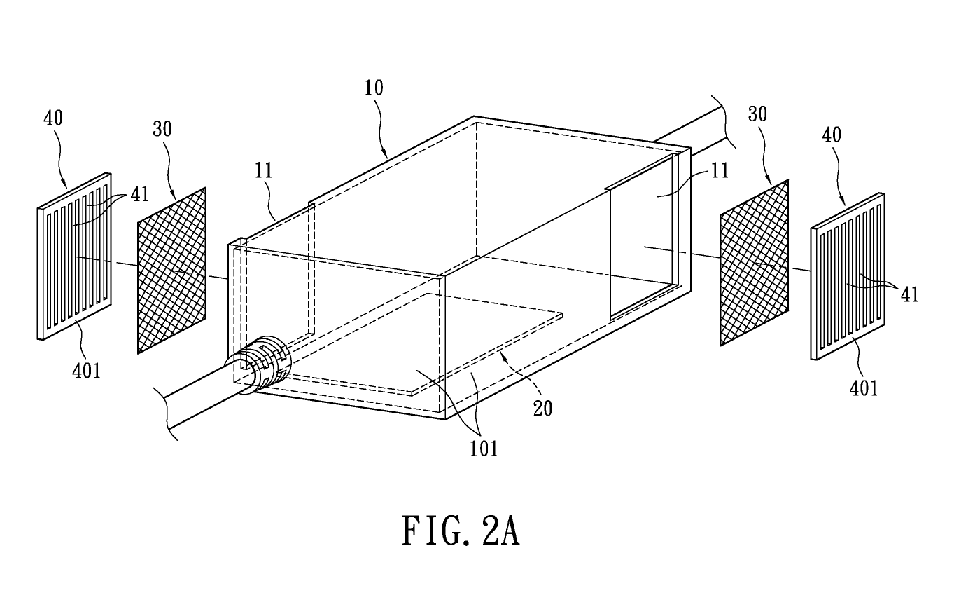

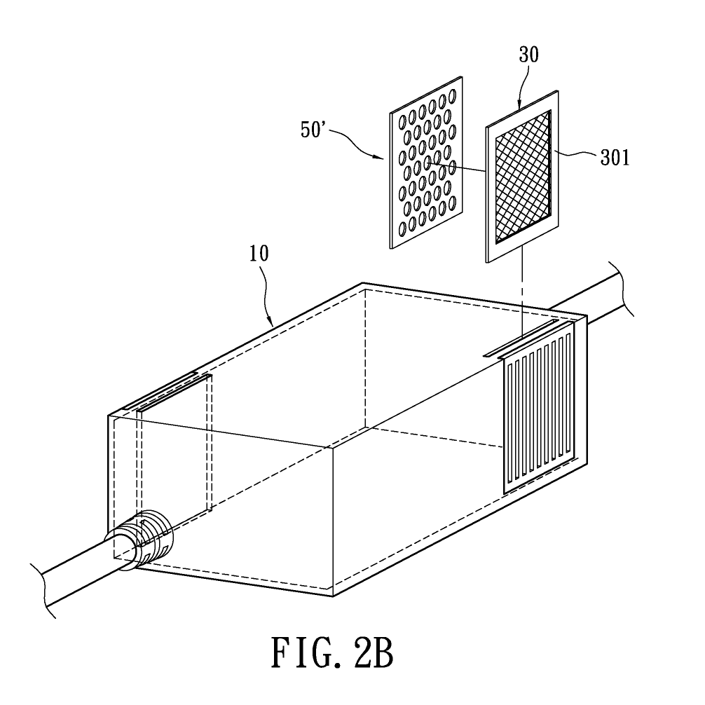

The power supply in accordance with the instant disclosure, such as the power adaptor shown in FIGS. 1 and 2A, comprises a housing unit 10, an electronic module 20, at least one breathable water repelling membrane units 30, and at least one membrane protection units 40. As particularly shown in the instant figures, the housing unit 10 has two ventilation ports 11. The electronic module 20 is hosted in the housing unit 10. Moreover, the breathable membrane unit 30 and the corresponding membrane protection unit 40 are correspondingly arranged to provide sealing coverage for the ventilation ports 11 of the housing unit 10.

The housing unit 10 is a hollow structure having a substantially rectangular outer shape. Particularly, the housing unit 10 may be of an integrally formed one piece construction, or it may be made-up with more than one sub-unit. The specific layout and arrangement of the housing unit 10 may depend on the desired level of accessibility and other operational requirements. The side walls of the housing unit 10 define a hollow enclosure for hosting the electronic module 20.

The electronic module 20 comprises electronic elements for performing power conversion/conditioning functions such as transforming electric power inputs between direct current (DC) and alternating current (AC) and/or regulating power input within the same type of current source. Typically, a great amount of heat will be generated during current converting operations. Excessive heat generated by the electronic module needs to be adequately dissipated away from the power supply to prevent heat damage to the sophisticated electronics hosted inside.

The housing unit 10 incorporates at least one ventilation port 11 for facilitating effective heat dissipation from the power supply. The power supply shown in the instant figures has two ventilation ports 11 correspondingly arranged on the side walls of the housing unit 10. The ventilation ports 11 can provide air communication between the interior and the exterior of the housing unit and enable convection of air, which in turn contribute to more effective heat exchange. It is to be noted that, the specific number and location of the ventilation port shall depend on specific operational requirements and should not be limited to the illustration of the instant figures. Generally, a larger number of ventilation ports may accommodate greater volume of air-flow, thus providing higher heat dissipating capacity.

However, the ventilation ports on the housing walls may inevitably allow undesired passage of water/fluid into the housing unit 10, thus causing damage to the electronic devices hosted therein. To overcome the problem of water/fluid damage to the electronic devices while retaining effective heat dissipating capability, the instant disclosure utilizes a breathable water-repelling membrane unit 30 to provide sealing coverage for the ventilation ports 11, thus ensuring healthy air circulation while preventing undesirable intrusion of water or other fluids into the housing unit 10.

The breathable water-repelling membrane unit 30 generally includes a porous substrate treated with a water repellent agent. The porous substrate is preferably of a thin-film material having adequate porosity for air passage. Example of porous substrate includes fiber paper, fiber cloth, metal/plastic net, or even high-tech breathable water-resistant fabric such as Gore-Tex™. Particularly, advanced waterproofing fabric such as Gore-Tex™ has excellent repelling capability for liquid water and other fluids, mainly due to a thin and porous fluoropolymer membrane (Teflon) coating bonded to the fabric, and is therefore an ideal choice for the application of the instant disclosure. Specifically, this type of membrane usually comprises about 9 billion pores per square inch and each pore is approximately 1/20,000 the size of a water droplet, making it impenetrable to liquid water or other fluids while still allowing the more autonomous water vapor molecules to pass through. On the other hand, conventional fabric may also be adequately adapted in the instant membrane unit upon proper treatment of suitable water-repelling agent. Particularly, treatment of conventional fabric with one or more water repellent agent is preferable to further enhance the water resisting capability thereof. The choice of water repellent agents and the method of their application are not limited. Moreover, the application of the selected water repellent agent may be spread-on or spray-on, as long as the repellent agent does not excessively impair the gas permeability of the membrane unit 30. It is to be noted that, the choice of thin-film substrate may depend on specific operational requirements, such as the actual power/heat generating level of the electronic module 20, the particular arrangement of the electronic components in the housing unit 10, or the structural layout of the membrane protection unit 40.

The breathable water repelling membrane may be arranged in the housing unit in a non-removable manner to restrict access of the internal electronics, thus preventing potential accident (such as electric shock) due to improper handling.

However, depending on the operational environment in which the device is operated, the membrane may trap dust and dirt and become less effective after being used for a period of time. Accordingly, the breathable water repelling membrane unit 30 may be removably arranged in the housing unit 10 for easy replacement. The removable design of the membrane unit is advantageous in that it provides an easier way for cleaning, or even the replacement of the membrane unit, thus maintaining the power supply at optimal operating condition. In a preferable embodiment (as shown in FIG. 2B), the breathable water repelling membrane unit 30 includes a thin porous substrate mounted in a frame 301 that provides structural support there-for. The housing unit 10 may include one or more slots arranged in a manner that, upon the insertion of the breathable water repelling membrane unit 30 therein, the membrane unit is retained in the correct position with respect to the corresponding ventilation port 11.

In general, the volume of air flow required to maintain a desirable heat-dissipating capacity should be directly proportional to the heat generating level of the electronic device. For example, basing on the design of the instant power supply, every 5-watt increment of gross heat loss from the electronic module 20 requires the addition of at least 0.3147 cubic feet per minutes (CFM) of air flow through the power supply to maintain a preferable level of heat-dissipating performance. Thus, the ratio of gross heat loss of the electronic module to the volume of air-flow is about 5-watt/0.3147-CFM.

A membrane protection unit 40 is correspondingly arranged over each of the breathable water repelling membrane units 30 to provide physical protection for the membrane unit. The thinness of the breathable water-repelling membrane unit 30 contributes to better air convection, which in turn leads to more effective heat exchange between the interior and exterior of the housing unit 10. However, the delicacy of the membrane units also makes them prone to physical damage, particularly from the external intrusion of sharp objects. Therefore, the employment of the membrane protection unit 40 on the outward-facing side of the membrane unit 30 may greatly enhance the operation life-expectancy of the breathable water-repelling membrane unit 30. The membrane protection unit 40 may be formed integrally with the housing unit 10 (not shown in the figures), or installed as a separate removable unit (as shown in the instant embodiment) to provide access to the membrane unit.

To enhance the aesthetic appearance and the structural unity of the power supply, the external outline 401 of the membrane protection unit 40 may be arranged in a coplanar manner with respect to the external surfaces 101 of the housing unit 10. Nevertheless, the specific layout and arrangement of the membrane protection unit 40 should depend on particular operational requirement. For example, the protection unit 40 may be either externally or internally mounted on the housing unit 10 with respect to the ventilation ports 11, and may be either protrusive or recessive with respect to the outer surfaces 101 of the housing unit 10.

The membrane protection unit 40 may include a vertically arranged fencing structure 41, with each two rails thereof having a slit in between to allow air passage. The fencing structure 41 is particularly designed to prevent external intrusion of sharp articles from contacting the membrane unit 30 and causing damage thereto. Thus, the specific layout and arrangement of the fencing structure 41 of the membrane protection unit 40 should depend upon particular operational requirements, and should not be limited to the illustration of the instant figures. For example, the fencing structure 41 of the membrane protection unit 40 may be horizontally or slantingly arranged, or even be of a net structure (not shown in the figures), as long as external hazardous objects can be kept away from directly harming the membrane unit 30.

The membrane protection units 40 are preferably separated from the breathable water-repelling membrane units 30 by a pre-determined distance. Having a pre-determined gap between the protection unit 40 and the membrane unit 30 is of particular importance for membrane units because the flow of air may cause the membrane unit to stick onto the inner surface of the membrane protection unit 40, thus reducing cross-section for the passage of air-flow. Moreover, the gap between the membrane unit 30 and the protection unit 40 for an out-going airflow passageway is preferably larger than that of an incoming airflow passageway, as the membrane unit 30 of an outlet port is more prone to the above-mentioned sticking effect onto the protection unit 40. Preferably, the distance between the membrane unit 30 and the protection unit 40 for an incoming airflow passageway is more than 1 mm, while the distance between that of an out-going airflow passageway is more than 3 mm. Particularly, the frame 301 as shown in FIG. 2B may be designed to concurrently serve as a spacer for maintaining the desirable distance between the membrane unit 30 and the protection unit 40.

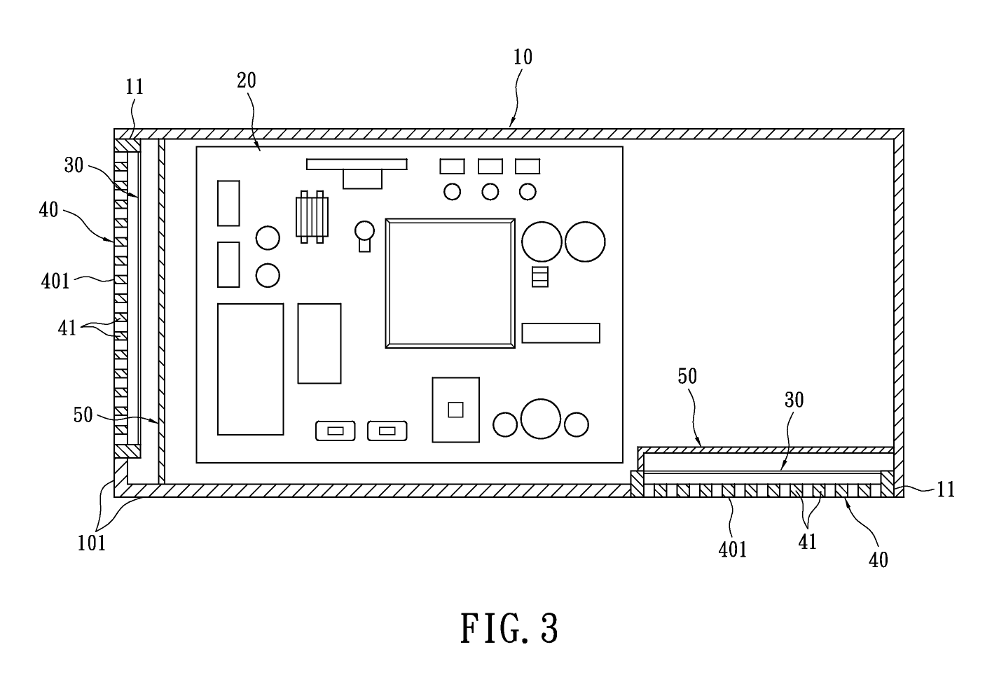

Optionally, the instant power supply may include a plurality of fire-resisting members 50 in the housing unit 10. The fire-resisting members 50 are passive fire protection structures arranged correspondingly between the membrane units 30 and the electronic module 20. Generally, the fire-resisting member 50 may be a petitioning structure having fire retardant characteristics. One example of a fire-resisting member 50 is a metallic mesh having fire retardant treatment arranged in the housing unit 10 behind the membrane unit 30, as shown in FIG. 3. Other structural arrangements, such as a fire retardant plate 50′, which is a porous plate made of fire retardant material, may be adapted to provide flame protection. It is preferable to have one fire-resisting member for each breathable water-repelling membrane structure 30. The placement of the fire-resisting member 50 is preferably in the proximity of the interior-facing side of the breathable membrane unit 30. For structural simplicity, the fire-resisting member 50′ may even be directly coupled to the membrane unit 30 as an integrated unit (as shown in FIG. 2B). Because the porous substrate of the membrane unit 30 often comprises thin material having ignition point lower than that of metals, the membrane unit risks a higher chance of catching on fire by an over-heating electronic module. By having a fire-resisting member 50 between the membrane unit 30 and the electronic module 20, the chances of the membrane unit 30 being caught on fire in the event of an accident may be reduced. The porosity of the fire-resisting member 50 should depend on the specific arrangement thereof in the housing unit and particular operational requirement. For instance, for a membrane unit 30 placed in close proximity to the electronic module 20, the corresponding fire-resisting member 50 may require smaller and less densely arranged holes to achieve the same flame retardant level as an identical membrane unit placed at a longer distance. However, it is desirable to provide the fire-resisting member 50 with adequate porosity that fulfills the desired level of flame proofing requirement without greatly hindering air flow through the membrane unit 30.

For power supplies that do not employ fire-resisting members, it is preferable to adapt a membrane filter having better fire resistance rating or maintain a greater distance between the membrane unit 30 and the electronic module 20. The preferable distance there-between is more than 13 mm.

The abovementioned embodiment utilizes natural convection of airflow to achieve heat-dissipation of the electronic module 20. With the sealing coverage provided by the breathable water-repelling membrane unit 30 and the protective unit 40, convection of air between the interior and the exterior of the housing unit 10 of the power supply may be effectively established, while external water/fluid being kept away from the electronic devices hosted therein.

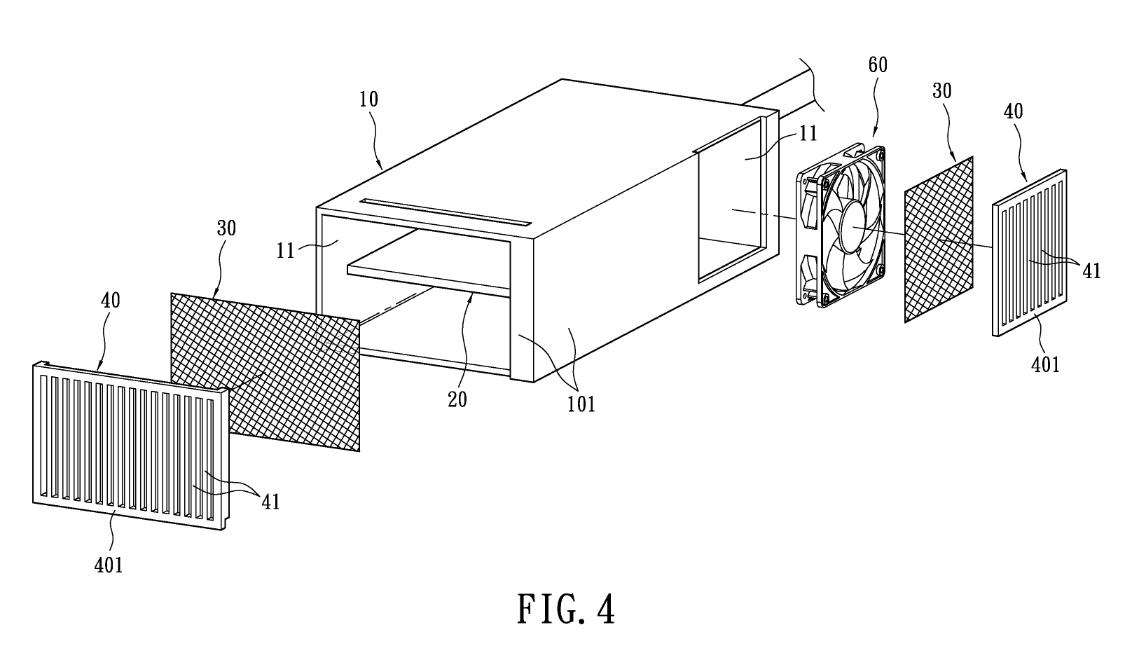

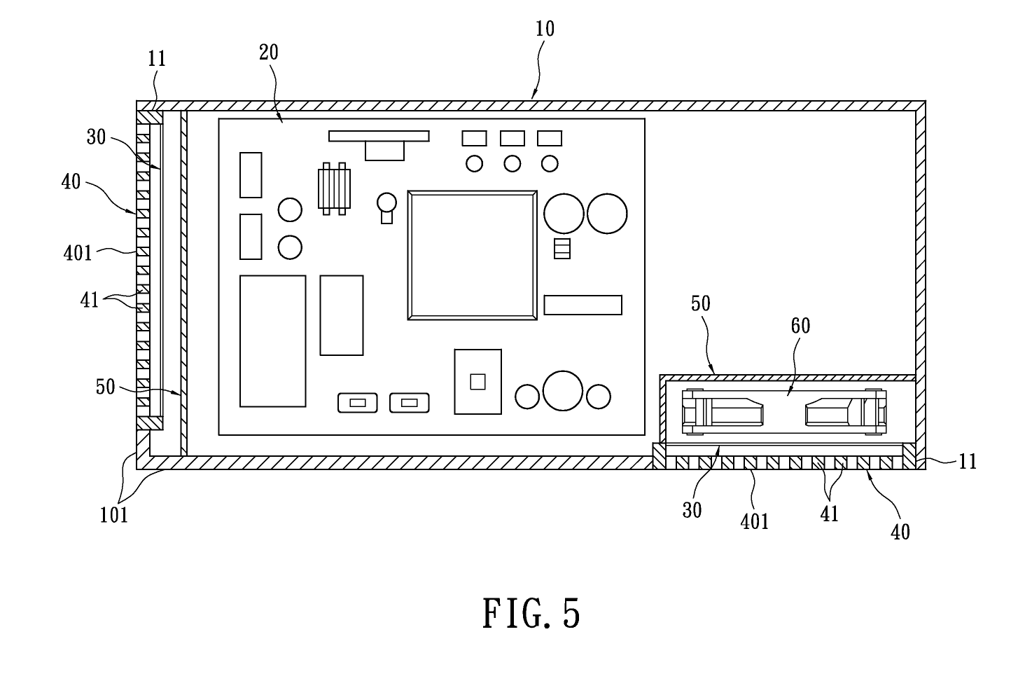

Please refer to FIGS. 4 and 5, which show another embodiment in accordance with the instant disclosure. It should be noted that the technical features of the instant embodiment share much similarities with the previous embodiment, except for the further inclusion of at least one airflow inducing device 60. The airflow inducing device 60 may be one or more electric fan unit correspondingly arranged in cooperation with the ventilation ports 11 to establish at least one air-inlet port and/or air-outlet port among the ventilation ports 11. The airflow inducing device 60 may serve as an active-induction unit to increase the rate of convection between the interior and the exterior of the housing unit 10 and therefore increase the heat-dissipating capacity for the electronic module 20. The placement of the airflow inducing device 60 is preferably in the proximity of the interior-facing side of the breathable membrane unit 30. Specifically, the airflow inducing device 60 is preferably disposed between the breathable membrane unit 30 and the electronic module 20.

Moreover, a proper distance between the airflow inducing device 60 and the interior-facing surface of the breathable membrane unit 30 should be maintained to reduce air-turbulence and achieve optimal airflow. Similar to the gap between the breathable membrane unit 30 and the membrane protection unit 40, having a pre-determined gap between the airflow inducing device 60 and the membrane unit 30 is of particular importance for membrane units because the flow of air may cause the membrane unit 30 to stick onto the surface of the airflow inducing device 60, thus negatively effecting the passage of air-flow. The arrangement of the airflow inducing device 60 may vary depending on particular designs and operational requirements. For example, the instant power supply may include more than one airflow inducing device to establish one or more pair of inlet and outlet ports to substantially increase the heat-dissipating capacity of the power supply. Nevertheless, the distance between the membrane unit 30 and the airflow inducing device 60 for an air-inlet port is preferably not less than 2 mm.

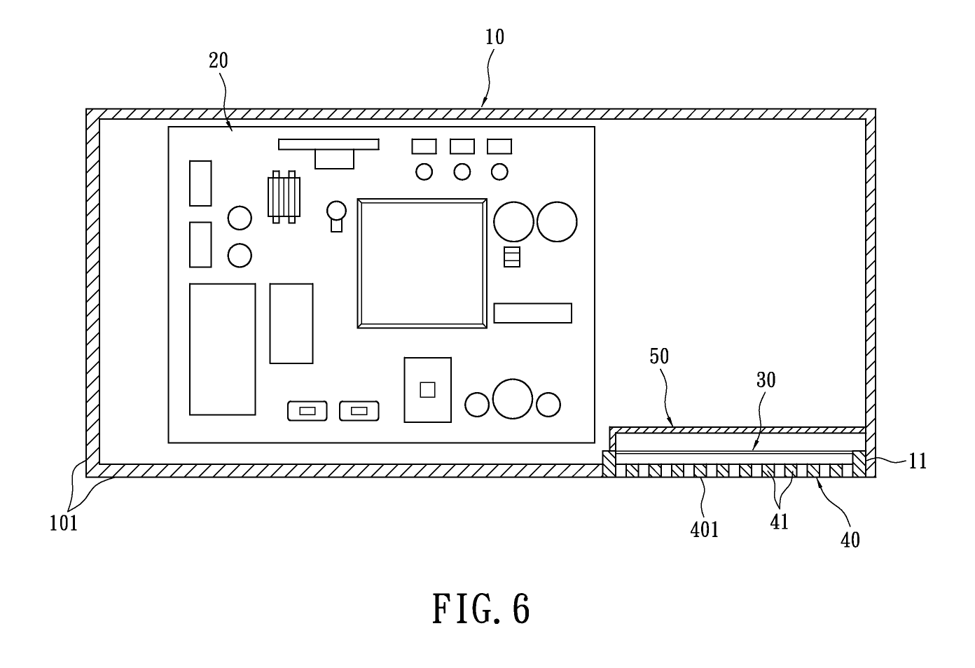

Please refer to FIG. 6, which shows yet another embodiment in accordance with the instant disclosure. While the instant embodiment retains many similar technical features of the previous embodiments, the instant example employs a single convection port on the housing unit 10. Specifically, the third embodiment utilizes a single ventilation port 11 on the housing unit in cooperation with a single breathable membrane unit 30, a membrane protection unit 40, and a fire-resisting member 50. Thus, convection and heat exchange of the power supply is carried out by a single ventilation port. The third embodiment places specific emphasis on structural simplicity, which in turn translates to lower manufacturing cost.

While the invention has been disclosed with respect to a limited number of embodiments, numerous modifications and variations will be appreciated by those skilled in the art. It is intended, therefore, that the following claims cover all such modifications and variations that may fall within the true spirit and scope of the invention.

What is claimed is:

1. A power supply having breathable water repelling structure, comprising:
a housing unit having at least one ventilation port;
an electronic module disposed in the housing unit;
at least one breathable water-repelling membrane unit sealingly covering the ventilation port; and
at least one membrane protection unit correspondingly arranged over the breathable water-repelling membrane unit.

2. The power supply of claim 1, wherein the breathable water-repelling membrane unit includes a porous substrate treated by at least one water-repelling agent.

3. The power supply of claim 1, wherein the breathable water-repelling membrane unit and the membrane protection unit are separated by a pre-determined distance.”

4. The power supply of claim 3, wherein the breathable water-repelling membrane unit includes a spacing frame and a porous substrate arranged therein, wherein the spacing frame separates the porous substrate and the membrane protection unit by the pre-determined distance.

5. The power supply of claim 4, wherein the housing unit includes at least one slot accessibly arranged in correspondence to the ventilation port for removably receiving the breathable water-repelling membrane unit.

6. The power supply of claim 1, wherein the at least one ventilation port include at least one inlet port and at least one outlet port, wherein the distance between the breathable water-repelling membrane unit and the membrane protection unit of the outlet port is larger than the distance between the breathable water-repelling membrane unit and the membrane protection unit of the inlet port.

7. The power supply of claim 6, wherein the distance between the breathable water repelling membrane unit and the membrane protection unit of the inlet port is not less than 1 mm, wherein the distance between the breathable water repelling membrane unit and the membrane protection unit of the outlet port is not less than 3 mm.

8. The power supply of claim 1, further comprising at least one air flow inducing device correspondingly arranged in the housing unit behind the breathable water-repelling membrane unit.

9. The power supply of claim 8, wherein the air flow inducing device is disposed at a distance not less than 2 mm from the corresponding breathable water repelling membrane.

10. The power supply of claim 1, further comprising at least one fire-resisting member disposed in the housing unit behind the breathable water-repelling membrane unit.

11. The power supply of claim 10, wherein the fire-resisting member is integrally coupled to the breathable water-repelling membrane unit.

12. The power supply of claim 1, wherein the external outline of the membrane protection unit is coplanar with the external surfaces of the housing unit.

13. The power supply of claim 1, wherein the membrane protection unit is formed integrally on the housing unit.

14. The power supply of claim 1, wherein the membrane protection unit is removably arranged on the housing unit.

15. The power supply of claim 1, wherein the electronic module is disposed not less than 13 mm from the interior-facing side of the breathable water-resisting membrane member

16. The power supply of claim 1, wherein the power supply is configured as a power adaptor.
